(19) United States
(12) Patent Application Publication
(10) Pub. No.: US 2021/0398932 A1
(43) Pub. Date: Dec. 23, 2021

(54) SEMICONDUCTOR STRUCTURE AND METHOD OF FORMING THE SAME

(71) Applicant: Yangtze Memory Technologies Co., Ltd., Wuhan City (CN)

(72) Inventors: Jun CHEN, Wuhan City (CN); Ziqun HUA, Wuhan City (CN); Siping HU, Wuhan City (CN); Jiawen WANG, Wuhan City (CN); Tao WANG, Wuhan City (CN); Jifeng ZHU, Wuhan City (CN); Taotao DING, Wuhan City (CN); Xinsheng WANG, Wuhan City (CN); Hongbin ZHU, Wuhan City (CN); Weihua CHENG, Wuhan City (CN); Shining YANG, Wuhan City (CN)

(73) Assignee: Yangtze Memory Technologies Co., Ltd., Wuhan City (CN)

(21) Appl. No.: 17/465,866

(22) Filed: Sep. 3, 2021

Related U.S. Application Data
(62) Division of application No. 16/378,518, filed on Apr. 8, 2019.
Application No. 16/378,518 is a continuation of application No. PCT/CN2018/093691, filed on Jun. 29, 2018.

(51) Int. Cl. H01L 23/00

(52) U.S. Cl. CPC H01L 24/29; H01L 24/27; H01L 24/08; H01L 24/32; H01L 2224/0812; H01L 2224/08145; H01L 2224/27452; H01L 2224/32145; H01L 2224/29186

(57) ABSTRACT

A method of forming a semiconductor structure, including steps of providing a first substrate, and forming a first bonding layer on a surface of the first substrate, wherein a material of the first bonding layer includes dielectric material of silicon, nitrogen and carbon.

### CROSS REFERENCE TO RELATED APPLICATIONS

This application is a divisional of application Ser. No. 16/378,518, filed on Apr. 8, 2019, which is further a continuation of PCT Application No. PCT/CN2018/093691 filed on Jun. 29, 2018, the entire contents of which are incorporated herein by reference.

### BACKGROUND OF THE INVENTION

### 1. Field of the Invention

The present invention generally relates to semiconductor technology, and more specifically, to a semiconductor structure and method of forming the same.

### 2. Description of the Prior Art

In the technology platform of a three-dimensional (3D) chip, at least two wafers with semiconductor devices formed thereon are usually bonded together through wafer bonding technology to increase the integration of IC. In current wafer bonding technology, silicon oxide based film or silicon nitride based film are usually used as a bonding film at the wafer bonding interface.

In prior art, silicon oxide film and silicon nitride film are used as a bonding film. However, the bonding strength of these kinds of film is not sufficient, so that defects easily happen in the process to affect the yield of product.

Furthermore, metal interconnections will be formed in the bonding film. In the process of hybrid bonding, the metal interconnections may easily cause diffusion phenomenon at the bonding interface to affect the performance of product.

Accordingly, how to increase the quality of wafer bonding is currently an urgent topic in the development of a 3D chip.

### SUMMARY OF THE INVENTION

The technical matter solved by the present invention is to provide a semiconductor structure and a method of forming the same.

The present invention provides a semiconductor structure, wherein the semiconductor structure includes a first substrate and a first bonding layer on the surface of first substrate. The material of first bonding layer includes dielectric materials like silicon (Si), nitrogen (N) and carbon (C).

Optionally, the atomic concentration of carbon in the first bonding layer is larger than 0% and smaller than 50%.

Optionally, the atomic concentration of carbon in the first bonding layer is uniform.

Optionally, the atomic concentration of carbon in the first bonding layer gradually changes along with the increase of thickness of the first bonding layer.

Optionally, the compactness of first bonding layer gradually changes along with the increase of thickness.

Optionally, the thickness of first bonding layer is larger than 100 Å.

Optionally, the semiconductor structure further includes a second substrate, wherein a second bonding layer is formed on the surface of second substrate, and the surfaces of second bonding layer and first bonding layer are correspondingly bonded and fixed together.

Optionally, the second bonding layer and the first bonding layer have the same material.

Optionally, the semiconductor structure further includes a first bonding pad penetrating through the first bonding layer and a second bonding pad penetrating through the second bonding layer, wherein the first bonding pad and the second bonding pad are correspondingly bonded and connected together.

The technical solution of the present invention further provides a method of forming a semiconductor structure, which includes the steps of providing a first substrate and forming a first bonding layer on the surface of first substrate. The material of first bonding layer includes dielectric material like silicon (Si), nitrogen (N) and carbon (C).

Optionally, the first bonding layer is formed by using chemical vapor deposition.

Optionally, the atomic concentration of carbon in the first bonding layer is larger than 0% and smaller than 50%.

Optionally, the atomic concentration of carbon in the first bonding layer is uniform.

Optionally, the atomic concentration of carbon in the first bonding layer gradually changes along with the increase of thickness of the first bonding layer.

Optionally, the compactness of first bonding layer gradually changes along with the increase of thickness.

Optionally, the thickness of first bonding layer is larger than 100 Å.

Optionally, the semiconductor structure forming method further includes a second substrate and a second bonding layer formed on the surface of second substrate, and the surfaces of second bonding layer and the surface of first bonding layer are correspondingly bonded and fixed together.

Optionally, the second bonding layer and the first bonding layer have the same material.

Optionally, the semiconductor structure forming method further includes the steps of forming a first bonding pad penetrating through the first bonding layer, forming a second bonding pad penetrating through the second bonding layer, and correspondingly bonding the first bonding pad and the second bonding pad when correspondingly bonding the surface of second bonding layer and the surface of first bonding layer.

The material of first bonding layer in the semiconductor structure of present invention includes dielectric material like silicon (Si), nitrogen (N) and carbon (C), which may provide higher bonding force in bonding process and may prevent the diffusion of metal materials at the bonding interface, thereby improving the performance of semiconductor structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 are schematic figures sequentially illustrating a forming process of a semiconductor structure in accordance with an embodiment of the present invention;

FIG. 5 is a schematic figure of a semiconductor structure in accordance with an embodiment of the present invention; and

FIG. 6 is a schematic figure of a semiconductor structure in accordance with an embodiment of the present invention.

### DETAILED DESCRIPTION

In the following detailed description of the invention, reference is made to the accompanying drawings, which form a part hereof, and in which is shown, by way of illustration, specific embodiments in which the semiconductor structure and the method of forming the same of the invention may be practiced.

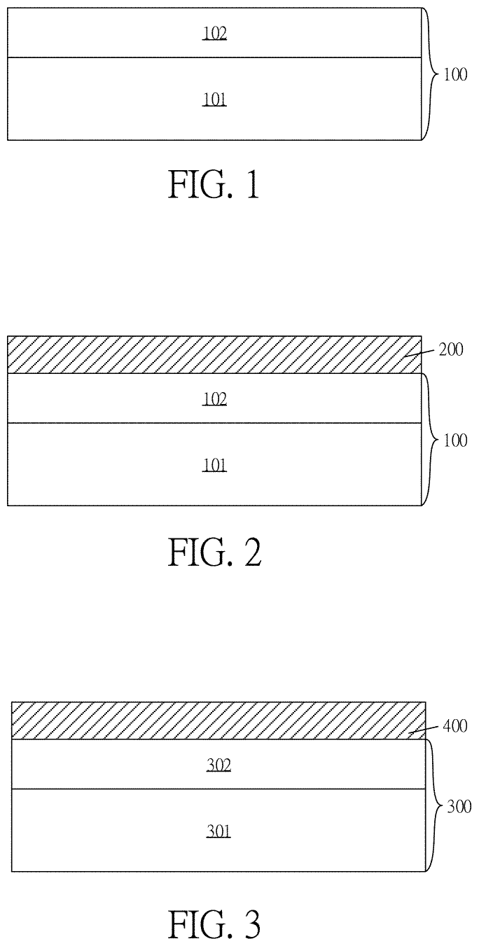

Please refer to FIG. 1 to FIG. 4, which are schematic figures sequentially illustrating a process of forming a semiconductor structure in accordance with an embodiment of the present invention.

Please refer to FIG. 1. First provide a first substrate 100.

The first substrate 100 includes a first semiconductor substrate 101, a first device layer 102 formed on the surface of first semiconductor substrate 101.

The first semiconductor substrate 101 may be single-crystal silicon substrate, germanium (Ge) substrate, silicon-germanium (SiGe) substrate, silicon-on-insulator (SOI) substrate or germanium-on-insulator (GOI) substrate, etc. Suitable first semiconductor substrate 101 may be selected depending on actual requirement of the device, but not limited thereto. In preferred embodiment, the first semiconductor substrate 101 is a single-crystal silicon wafer.

The first device layer 102 includes semiconductor devices formed on first semiconductor substrate 101, metal interconnections connecting the semiconductor devices, dielectric layers covering the semiconductor devices and the metal interconnections, etc. The first device layer 102 may be multilayer or single-layer structure. In the embodiment, the first device layer 102 includes dielectric layers and 3D NAND structure formed in the dielectric layers.

Please refer to FIG. 2. A first bonding layer 200 is formed on the surface of first substrate 100. The material of first bonding layer 201 includes the dielectric materials like silicon (Si), nitrogen (N) and carbon (C).

The first bonding layer 200 may be formed by using individual chemical vapor deposition (CVD) processes. In the embodiment, the first bonding layer 200 is formed by using plasma enhanced chemical vapor deposition (PECVD) processes.

The material of first bonding layer 200 includes the dielectric materials like silicon (Si), nitrogen (N) and carbon (C). The first bonding layer 200 may be further doped with at least one element of oxygen (O), hydrogen (H), phosphorus (P) and fluorine (F), depending on the reagent gas using in the PECVD process and the requirement of products. For example, the material of first bonding layer 200 may be doped silicon nitride, doped silicon oxynitride and doped silicon carbonitride, etc.

In an embodiment, the reagent gas using in the PECVD process of forming the first bonding layer 200 includes one of trimethylsilane or tetramethylsilane and NH₃ , with the flow ratio of trimethylsilane or tetramethylsilane to NH₃ larger than 0.5 under a radio frequency power larger than 300 W.

In another embodiment, the first bonding layer 200 may be formed by performing a treatment to the dielectric materials. For example, after a silicon oxide film is formed on the surface of first substrate 100, performing a nitrogen doping process to the silicon oxide film to form the first bonding layer 200. Suitable material and treatment for the dielectric film may be selected depending on the materials of first bonding layer 200 to be formed.

The element concentration in the first bonding layer 200 may be adjusted by controlling the process parameters of forming the first bonding layer 200, so that the bonding force between the first bonding layer 200 and the first device layer 102, the dielectric constant of first bonding layer 200, and the bonding force to other bonding layers may, therefore, be adjusted.

The carbon in first bonding layer 200 may efficiently increase the bonding force between the first bonding layer 201 and other bonding layers in bonding process. The higher the carbon concentration, the stronger the bonding force to other bonding layer resulted in bonding process. In an embodiment, the atomic concentration of carbon in the first bonding layer 200 is larger than 0% and smaller than 50%.

Since the bonding force between different materials is related to material compositions at both sides of the bonding interface, the bonding force would get stronger if the material compositions are similar. In order to further increase the bonding force between the first bonding layer 200 and the first device layer 102, process parameters may be gradually adjusted during the formation of first bonding layer 200 to gradually change element concentrations in the first bonding layer 200, so that the material composition of first device layer 102 and first bonding layer 200 would be similar. In an embodiment, the parameters of deposition process are adjusted along with the increase of thickness of the first bonding layer 200 during the process of forming the first bonding layer 200, so that the carbon atomic concentration in the first bonding layer 200 may gradually change along with the increase of thickness of the first bonding layer 200, and the surface of first bonding layer 200 would have maximum carbon concentration. In another embodiment, the carbon atomic concentration may be gradually decreased or may be gradually increased then gradually decreased along with the increase of thickness of the first bonding layer 200. In another embodiment, the parameters of deposition process may remain unchanged during the formation of first bonding layer 200 so that the element concentrations in different thickness levels of the first bonding layer 200 may also remain unchanged.

In another embodiment, the compactness of first bonding layer 200 may be gradually changed along with the increase of thickness of the first bonding layer 200 by adjusting process parameters. For example, up from the surface of first device layer 102, the compactness of first bonding layer 200 may gradually increase, gradually decrease, or gradually increase then gradually decrease. The compactness of first bonding layer 200 and first device layer 102 are similar at interface.

The thickness of first bonding layer 201 cannot be too small to ensure that the first bonding layer 200 have sufficient thickness when bonding the first bonding layer 200 to other bonding layers. In an embodiment, the thickness of first bonding layer 200 is larger than 100 Å.

Please refer to FIG. 3. In another embodiment, the method further includes providing a second substrate 300 and forming a second bonding layer 400 on the surface of second substrate 300.

The second substrate 300 includes a second semiconductor substrate 301 and a second device layer 302 on the surface of second semiconductor substrate 301.

The second bonding layer 400 is formed on the surface of second device layer 302 by using CVD process. The material of second bonding layer 400 may be silicon oxide or silicon nitride.

In the embodiment, the material of second bonding layer 400 may be dielectric material like silicon (Si), nitrogen (N) and carbon (C). Please refer to the description of first bonding layer 200 in the embodiment above. No redundant description will be therein provided. In an embodiment, the materials of second bonding layer 400 and first bonding layer 200 are the same.

Please refer to FIG. 4. The surfaces of second bonding layer 400 and first bonding layer 200 are correspondingly bonded and fixed.

Both of the second bonding layer 400 and the first bonding layer 200 include carbon element, which is partially in the form of —CH₃. The —CH₃ may be easily oxidized into —OH and may form Si—O bonds in the bonding process, so that more Si—O bonds may be formed on the bonding interface to provide stronger bonding force. In an embodiment, the bonding force between the second bonding layer 400 and the first bonding layer 200 is larger than 1.7 J/m², while the bonding force in prior art is usually smaller than 1.5 J/m² since its bonding layer contains no carbon element.

In an embodiment, the first substrate 100 is a substrate with 3D NAND memory formed thereon, and the second substrate 200 is a substrate with peripheral circuit formed thereon.

In another embodiment, the above-mentioned bonding layer may be formed on both sides of a substrate to realize the bonding solution with multiple substrates.

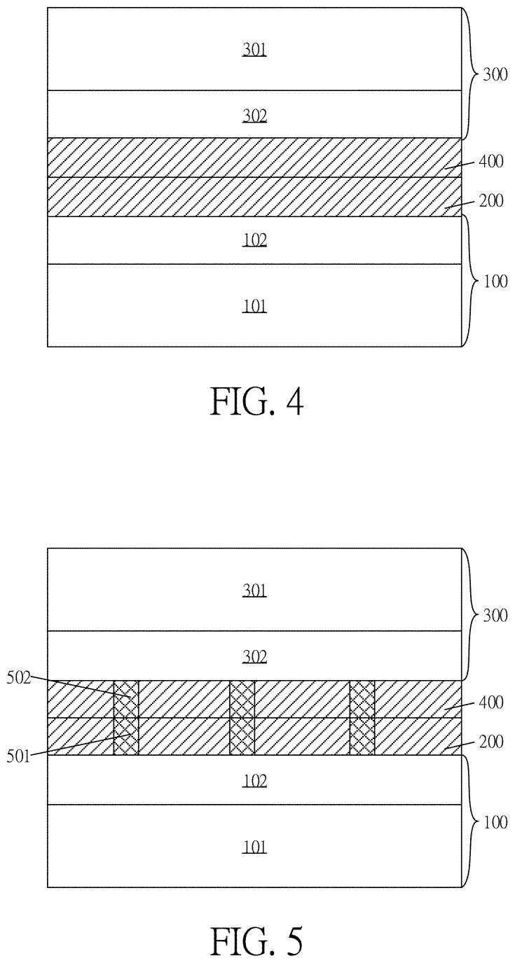

Please refer to FIG. 5. In another embodiment, the method further includes forming a first bonding pad 501 penetrating through the first bonding layer 200, forming a second bonding pad 502 penetrating through the second bonding layer 400, correspondingly bonding the first bonding pad 501 and the second bonding pad 502 when correspondingly bonding the surface of second bonding layer 400 to the surface of first bonding layer 200.

The first bonding pad 501 and the second bonding pad 502 may be connected to semiconductor devices and metal interconnections in the first device layer 102 and the second device layer 302, respectively.

The method of forming first bonding pad 501 includes: performing a patterning process to the first bonding layer 200 to form openings penetrating through the first bonding layer 200, filling the openings with metal material and performing a planarization process to form first bonding pads 501 filling up the openings, using the same method to form the second bonding pad 502 in the second bonding layer 400, and bonding the first bonding pad 501 and the second bonding pad 502 to realize the electrical connection between the semiconductor devices in first device layer 102 and second device layer 302.

The materials of first bonding pad 501 and second bonding pad 502 may be metal material like copper (Cu) and tungsten (W), etc. The carbon element included in the first bonding layers 200 and the first bonding layers 400 may efficiently block and prevent the material diffusion of first bonding pads 501 and second bonding pad 502 at the bonding interface, thereby improving the performance of semiconductor structure.

The above-described method may also be used in the bonding of multiple substrates.

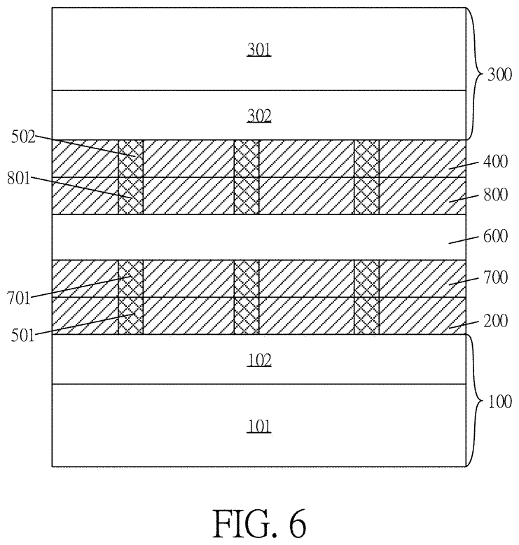

Please refer to FIG. 6. In an embodiment of present invention, the method further includes: providing a third substrate 600, forming a third bonding layer 700 and a fourth bonding layer 800 respectively at two opposite surfaces of the third substrate 600, bonding the surfaces of third bonding layer 700 and first bonding layer 200, bonding the surfaces of fourth bonding layer 800 and second bonding layer 400 to form tri-layer bonding structure.

The material and method of forming third bonding layer 700 and fourth bonding layer 800 may refer to the material and forming method of first bonding layer 200 in the embodiment above. No redundant description will be therein provided.

In the embodiment, the method further includes: forming a third bonding pad 701 in the third bonding layer 700, forming a fourth bonding pad 801 in the fourth bonding layer 800, bonding the third bonding pad 701 and the first bonding pad 501, and bonding the fourth bonding pad 801 and the second bonding pad 502.

In another embodiment, the above-described method may be used to form a bonding structure with at least four layers.

In the embodiment above, forming a bonding layer with dielectric material like Si, N and C on the substrate surface may provide higher bonding force at bonding interface after bonding and may prevent the diffusion of metal materials at the bonding interface, thereby improving the performance of semiconductor structure.

Please note that, in the technical solution of present invention, the type of semiconductor devices in individual substrates of semiconductor structure is not limited to those mentioned in the embodiments. In addition to 3D NAND, it may be complementary metal-oxide-semiconductor (CMOS), CMOS image sensor (CIS) or thin-film transistor (TFT), etc.

The embodiment of present invention further provide a semiconductor structure.

Please refer to FIG. 2, which is a schematic figure of a semiconductor structure in an embodiment of the present invention.

The semiconductor structure may include a first substrate 100 and a first bonding layer 200 on the surface of first substrate 100. The material of first bonding layer 200 includes dielectric material like silicon, nitrogen and carbon, and the material of first bonding layer 200 includes dielectric material like silicon and nitrogen.

The first substrate 100 includes a first semiconductor substrate 101, a first device layer 102 formed on the surface of first semiconductor substrate 101.

The first semiconductor substrate 101 may be single-crystal silicon substrate, germanium (Ge) substrate, silicon-germanium (SiGe) substrate, silicon-on-insulator (SOI) substrate or germanium-on-insulator (GOI) substrate, etc. Suitable first semiconductor substrate 101 may be selected depending on actual requirement of the device, but not limited thereto. In preferred embodiment, the first semiconductor substrate 101 is a single-crystal silicon wafer.

The first device layer 102 includes semiconductor devices formed on first semiconductor substrate 101, metal interconnections connecting the semiconductor devices, dielectric layers covering the semiconductor devices and the metal interconnections, etc. The first device layer 102 may be multilayer or single-layer structure. In an embodiment, the first device layer 102 includes dielectric layers and 3D NAND structure formed in the dielectric layers.

The material of first bonding layer 200 includes the dielectric materials like silicon (Si), nitrogen (N) and carbon (C). The first bonding layer 200 may be further doped with at least one element of oxygen (O), hydrogen (H), phosphorus (P) and fluorine (F), depending on the reagent gas using in the PECVD process and the requirement of products. For example, the material of first bonding layer 200 may be doped silicon nitride, doped silicon oxynitride and doped silicon carbonitride, etc.

The element concentration in the first bonding layer 200 may be adjusted by controlling the process parameters of forming the first bonding layer 200, so that the adhesive force between the first bonding layer 200 and the first device layer 102, the dielectric constant of first bonding layer 200, and the bonding force to other bonding layers after bonding process may, therefore, be adjusted.

The carbon in first bonding layer 200 may efficiently increase the bonding force between the first bonding layer 200 and other bonding layer in bonding process. The higher the carbon concentration, the stronger the bonding force to other bonding layers in bonding process. In an embodiment, the atomic concentration of carbon in the first bonding layer 200 is larger than 0% and smaller than 50%.

Since the bonding force between different materials is related to material compositions at both sides of the bonding interface, the bonding force would get stronger if the material compositions are similar. In order to further increase the adhesive force between the first bonding layer 200 and the first device layer 102, the element concentrations in the first bonding layer 200 would gradually change along with the thickness of first bonding layer 200, so that the material composition of first bonding layer 200 and the material at two sides of first device layer 102 would be similar. In an embodiment, the carbon atomic concentration in the first bonding layer 200 may be gradually increased along with the increase of thickness of the first bonding layer 200, so that the surface of first bonding layer 200 would have maximum carbon concentration. In another embodiment, the carbon atomic concentration in the first bonding layer 200 may be gradually decreased or may be gradually increased then gradually decreased along with the increase of thickness of the first bonding layer 200. In another embodiment, the element concentrations in different thickness levels of the first bonding layer 200 may remain unchanged to provide uniform atomic concentration.

In another embodiment, the compactness of first bonding layer 200 may be gradually changed along with the increase of thickness of the first bonding layer 200. For example, up from the surface of first device layer 102, the compactness of first bonding layer 200 may gradually increases, gradually decreases, or gradually increases then gradually decreases. The compactness of first bonding layer 200 and first device layer 102 are similar at interface.

The thickness of first bonding layer 201 cannot be too small to ensure that the first bonding layer 200 have sufficient thickness when bonding the first bonding layer 200 to other bonding layers. In an embodiment, the thickness of first bonding layer 200 is larger than 100 Å.

Please refer to FIG. 4, which is a schematic figure of a semiconductor structure in accordance with another embodiment of the present invention.

In another embodiment, the semiconductor structure further includes a second substrate 300 and forming a second bonding layer 400 on the surface of second substrate 300. The surfaces of second bonding layer 400 and first bonding layer 200 are correspondingly bonded and fixed together.

The second substrate 300 includes a second semiconductor substrate 301 and a second device layer 302 on the surface of second semiconductor substrate 201. The material of second bonding layer 400 may be silicon oxide or silicon nitride. The material of second bonding layer 400 may also be dielectric material like silicon (Si), nitrogen (N) and carbon (C). Please refer to the description of first bonding layer 200 in the embodiment above. No redundant description will be therein provided. In an embodiment, the materials of second bonding layer 400 and first bonding layer 200 are the same.

The surfaces of second bonding layer 400 and first bonding layer 200 are correspondingly bonded and fixed together. Since both of the second bonding layer 400 and the first bonding layer 200 include carbon element, which is partially in the form of —CH₃. The —CH₃ maybe easily oxidized into —OH and may form Si—O bonds in the bonding process, so that more Si—O bonds may be formed in the bonding interface to provide stronger bonding force.

In another embodiment, the semiconductor structure may include at least three substrates, wherein adjacent substrates are all bonded together by using the composite bonding layer in the embodiment of present invention.

Please refer to FIG. 5, which is a schematic figure of a semiconductor structure in accordance with another embodiment of the present invention.

In the embodiment, the semiconductor structure further includes a first bonding pad 501 penetrating through the first bonding layer 200, a second bonding pad 502 penetrating through the second bonding layer 400, wherein the surface of second bonding layer 400 and the surface of first bonding layer 200 are correspondingly bonded and fixed together, and the first bonding pad 501 and the second bonding pad 502 are also correspondingly bonded and connected together.

The first bonding pad 501 and the second bonding pad 502 may be connected to semiconductor devices and metal interconnections in the first device layer 102 and the second device layer 302, respectively.

The materials of first bonding pad 501 and second bonding pad 502 may be metal material like copper (Cu) and tungsten (W), etc. The carbon element included in the first bonding layers 200 and the second bonding layers 401 may efficiently block and prevent the material diffusion of first bonding pads 501 and second bonding pad 502 at the bonding interface, thereby improving the performance of semiconductor structure.

In an embodiment, the first substrate 100 is a substrate with 3D NAND memory formed thereon, and the second substrate 200 is a substrate with peripheral circuit formed thereon.

Please refer to FIG. 6, which is a schematic figure of a semiconductor structure in accordance with another embodiment of the present invention.

In the embodiment, the semiconductor structure further includes a third substrate 600. A third bonding layer 700 and a fourth bonding layer 800 are formed respectively at two opposite surfaces of the third substrate 600, wherein the surfaces of third bonding layer 700 and first bonding layer 200 are correspondingly bonded and fixed together, and the surfaces of fourth bonding layer 800 and second bonding layer 400 are bonded and fixed together, to constitute a tri-layer bonding structure.

The material and structure of third bonding layer 700 and fourth bonding layer 800 may refer to the ones of first bonding layer 200 in the embodiment above. No redundant description will be therein provided.

In the embodiment, a third bonding pad 701 is further formed in the third bonding layer 700, and a fourth bonding pad 801 is further formed in the fourth bonding layer 800, wherein the third bonding pad 701 and the first bonding pad 501 are bonded together, and the fourth bonding pad 801 and the second bonding pad 502 are bonded together.

In another embodiment, the above-described method may be used to form a bonding structure with at least four layers.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a semiconductor structure, comprising:
providing a first substrate; and
forming a first bonding layer on a surface of said first substrate, wherein a material of said first bonding layer comprises dielectric material of silicon, nitrogen and carbon.

2. The method of forming a semiconductor structure of claim 1, wherein said first bonding layer is formed by using chemical vapor deposition process.

3. The method of forming a semiconductor structure of claim 1, wherein an atomic concentration of carbon in said first bonding layer is larger than 0% and smaller than 50%.

4. The method of forming a semiconductor structure of claim 1, wherein an atomic concentration of carbon in said first bonding layer is uniform.

5. The method of forming a semiconductor structure of claim 1, wherein said atomic concentration of carbon in said first bonding layer gradually changes along with the increase of thickness of said first bonding layer.

6. The method of forming a semiconductor structure of claim 1, wherein a compactness of said first bonding layer gradually changes along with the increase of thickness of said first bonding layer.

7. The method of forming a semiconductor structure of claim 1, wherein a thickness of said first bonding layer is larger than 100 Å.

8. The method of forming a semiconductor structure of claim 1, further comprising:
providing a second substrate;
forming a second bonding layer on a surface of said second substrate; and
correspondingly bonding a surface of said second bonding layer to a surface of said first bonding layer.

9. The method of forming a semiconductor structure of claim 8, wherein said second bonding layer and said first bonding layer have the same material.

10. The method of forming a semiconductor structure of claim 8, further comprising:
forming a first bonding pad penetrating through said first bonding layer;
forming a second bonding pad penetrating through said second bonding layer; and
correspondingly bonding said first bonding pad and said second bonding pad when bonding said surface of said second bonding layer to said surface of said first bonding layer.
